(19) United States
(12) Patent Application Publication
(10) Pub. No.: US 2025/0174962 A1
(43) Pub. Date: May 29, 2025

(54) LIGHT-EMITTING DEVICE

(71) Applicant: NICHIA CORPORATION, Anan-shi (JP)

(72) Inventor: Tadayuki KITAJIMA, Itano-gun (JP)

(21) Appl. No.: 18/935,419

(22) Filed: Nov. 1, 2024

(30) Foreign Application Priority Data
Nov. 29, 2023 (JP) 2023-201363

(51) Int. Cl. H01S 5/02257; H01S 5/02315; H01S 5/02345

(52) U.S. Cl. CPC H01S 5/02257; H01S 5/02315; H01S 5/02345

(57) ABSTRACT

A light-emitting device includes a semiconductor laser element, an optical member, and a mounting member. The semiconductor laser element has a light-emitting surface. The optical member has a light incident surface and includes a conductive portion. The mounting member has a mounting surface on which first and second conductive regions, and an insulating region are provided. The second conductive region is insulated from the first conductive region via the insulating region. The semiconductor laser element is disposed in the first conductive region of the mounting surface. The optical member is disposed on the mounting surface such that the conductive portion and the mounting surface face each other and the conductive portion overlaps at least portions of the first and second conductive regions in a plan view. The semiconductor laser element is electrically connected to the second conductive region via the conductive portion.

### CROSS-REFERENCE TO RELATED APPLICATION

This application claims priority to Japanese Patent Application No. 2023-201363, filed on Nov. 29, 2023, the disclosure of which is hereby incorporated herein by reference in its entirety.

### TECHNICAL FIELD

The present disclosure relates to a light-emitting device.

### BACKGROUND

Japanese Patent Publication No. 2020-144363 discloses a light-emitting device including a semiconductor laser element, a wavelength conversion member including a wavelength conversion portion and a reflective member, a base portion on which the semiconductor laser element is disposed and to which the wavelength conversion member is fixed, and a conductive film provided at the reflective member in the vicinity of the wavelength conversion portion. The light-emitting device includes a configuration of detecting an abnormality from a change in an electrical connection state with respect to the conductive film, and the conductive film serves as an abnormality detection element for detecting an abnormality in the wavelength conversion portion.

### SUMMARY

One aspect of the present disclosure is directed to realize a light-emitting device including a configuration of stopping light emission from a semiconductor laser element according to the state of an optical member.

Another aspect of the present disclosure is directed to realize a small-size light-emitting device with a semiconductor laser element and an optical member disposed in a package internal space.

Another aspect of the present disclosure is directed to realize an abnormality detection while reducing the number of parts.

In one or more of the embodiments disclosed in the present specification, one or more of the above-described aspects may be achieved in combination.

A light-emitting device according to an embodiment includes: a semiconductor laser element, an optical member, and a mounting member. The semiconductor laser element has a light-emitting surface from which light is emitted. The optical member has a light incident surface on which light emitted from the light-emitting surface of the semiconductor laser element is incident. The optical member includes a conductive portion. The mounting member has a mounting surface on which a first conductive region, an insulating region, and a second conductive region are provided. The second conductive region is insulated from the first conductive region via the insulating region. The semiconductor laser element is disposed in the first conductive region of the mounting surface. The optical member is disposed on the mounting surface such that the conductive portion and the mounting surface face each other and the conductive portion overlaps at least a portion of the first conductive region and at least a portion of the second conductive region in a plan view seen along a direction perpendicular to the mounting surface. The semiconductor laser element is electrically connected to the second conductive region via the conductive portion.

In at least one of one or more disclosures disclosed by the embodiments, a light-emitting device including a configuration of stopping light emission from a semiconductor laser element according to the state of an optical member can be realized.

### BRIEF DESCRIPTION OF DRAWINGS

FIG. 1A is a schematic perspective view of a light-emitting device according to a first embodiment.

FIG. 1B is a schematic perspective view of the light-emitting device according to the first embodiment illustrated in a transparent manner.

FIG. 2A is a schematic top view of the light-emitting device according to the first embodiment corresponding to FIG. 1B.

FIG. 2B is a schematic bottom view of the light-emitting device according to the first embodiment.

FIG. 3 is a schematic cross-sectional view of the light-emitting device taken along a cross-sectional line III-III in FIG. 2A.

FIG. 4 is a schematic top view of the light-emitting device according to the first embodiment, in the state in which a lid body is removed.

FIG. 5 is a schematic top view of the light-emitting device according to the first embodiment, in the state in which the lid body and an optical member are removed.

FIG. 6 is a schematic perspective view of a submount according to the first embodiment.

FIG. 7 is a schematic top view of the submount according to the first embodiment.

FIG. 8 is a schematic bottom view of the submount according to the first embodiment.

FIG. 9A is a schematic cross-sectional view of the submount taken along the cross-sectional line IXA-IXA of FIG. 7.

FIG. 9B is a schematic cross-sectional view of the submount changed in scale from FIG. 9A for visibility to illustrate the structure of the submount.

FIG. 10 is a schematic perspective view of the optical member according to the first embodiment.

FIG. 11 is a schematic bottom view of the optical member according to the first embodiment.

FIG. 12 is a schematic cross-sectional view of the optical member taken along the cross-sectional line XII-XII in FIG. 10.

FIG. 13A is a schematic perspective view of a light-emitting device according to a second embodiment.

FIG. 13B is a schematic perspective view of the light-emitting device according to the second embodiment illustrated in a transparent manner.

FIG. 14A is a schematic top view of the light-emitting device according to the second embodiment corresponding to FIG. 13B.

FIG. 14B is a schematic bottom view of the light-emitting device according to the second embodiment.

FIG. 15 is a schematic cross-sectional view of the light-emitting device taken along a cross-sectional line XV-XV in FIG. 14A.

FIG. 16 is a schematic top view of the light-emitting device according to the second embodiment, in the state in which a lid body is removed.

FIG. 17 is a schematic top view of the light-emitting device according to the second embodiment, in the state in which the lid body and an optical member are removed.

FIG. 18 is a schematic perspective view of a base according to the second embodiment.

FIG. 19 is a schematic top view of the base according to the second embodiment.

### DETAILED DESCRIPTIONS

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present specification and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present specification or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one part in a manufacturing process. Meanwhile, the term “portion” refers to an object that does not have to be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In this case, the components denoted as “first” and “second” in the claims refer to the components termed “first” and “third” in the present specification, respectively. This rule applies to not only components but also other objects in a reasonable and flexible manner.

An embodiment for implementing the present invention will be described below. A specific embodiment for implementing the present invention will be described below with reference to the drawings. An embodiment for implementing the present invention is not limited to the specific embodiment. That is, the embodiment illustrated by the drawings is not the only form in which the present invention is implemented. Sizes and positional relationships of members illustrated in each of the drawings may sometimes be exaggerated in order to facilitate understanding.

### First Embodiment

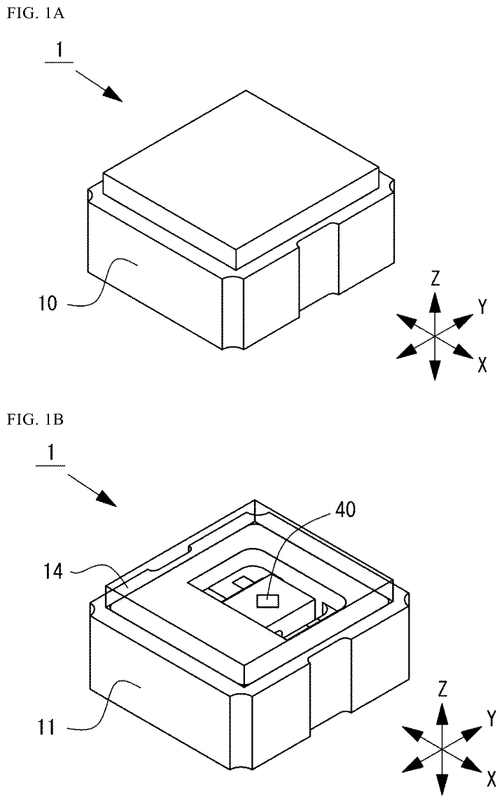

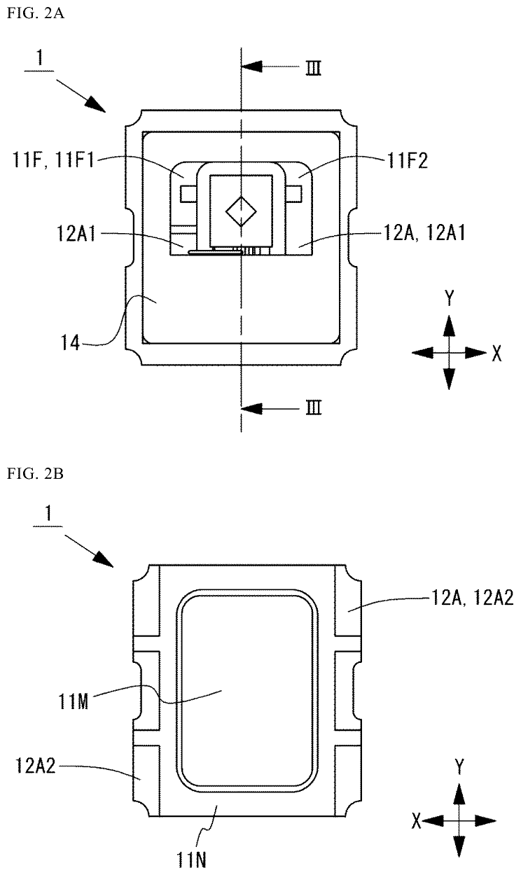

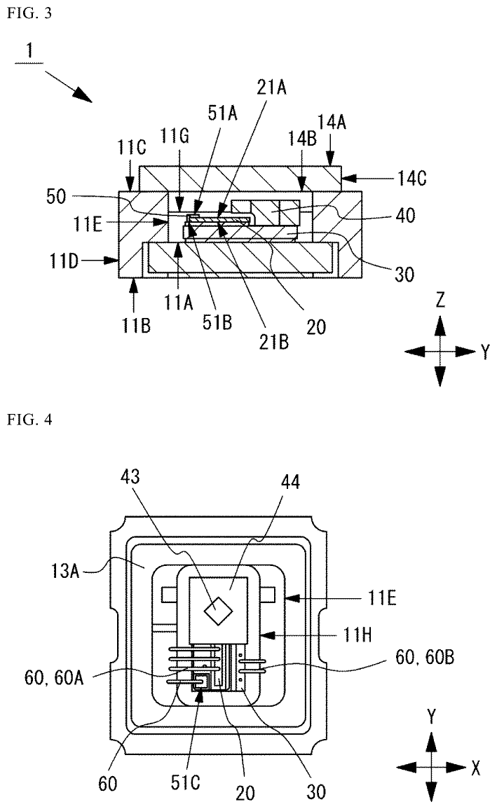

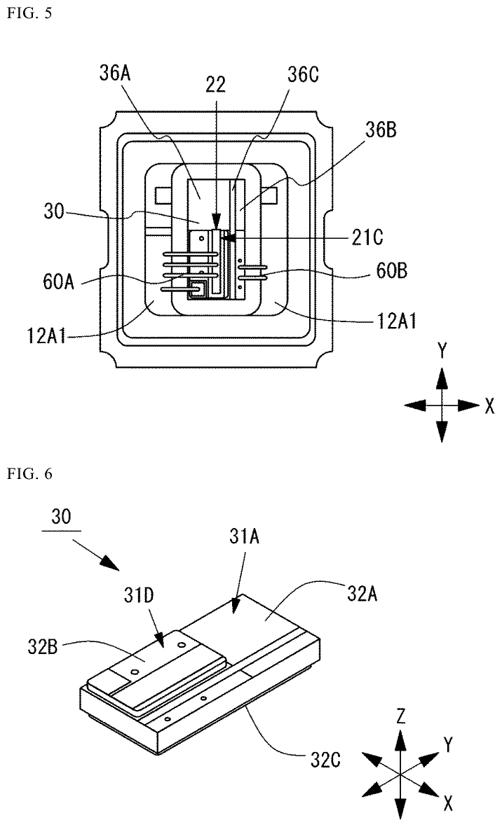

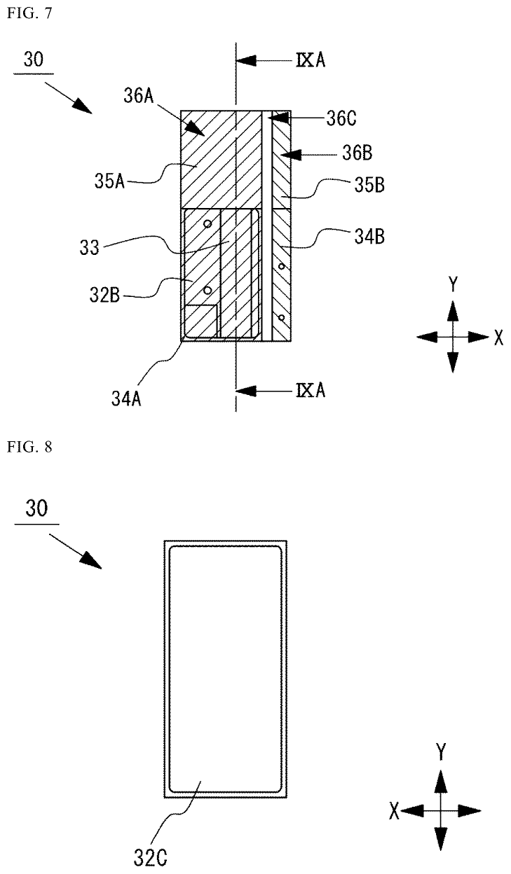

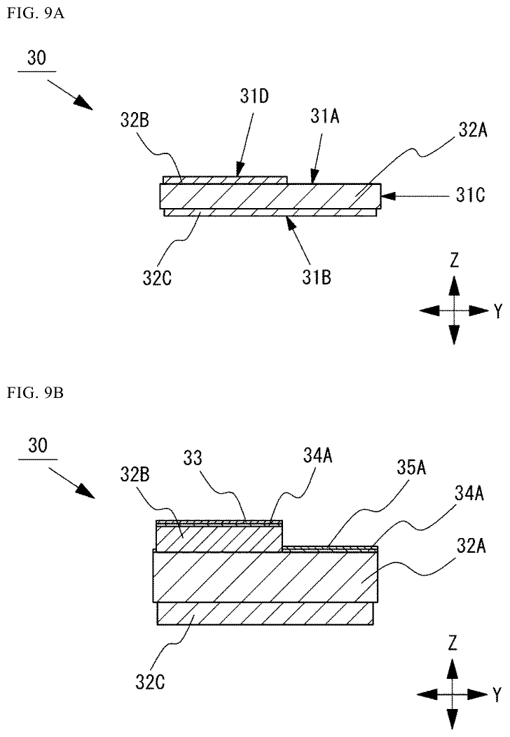

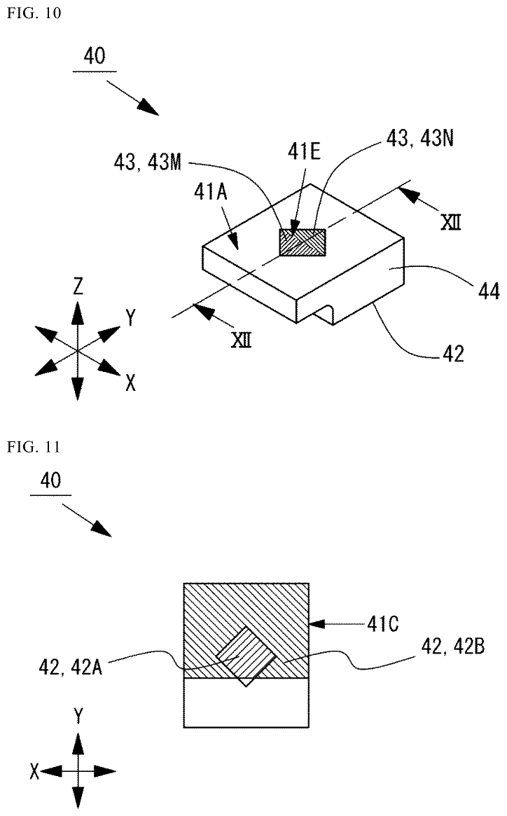

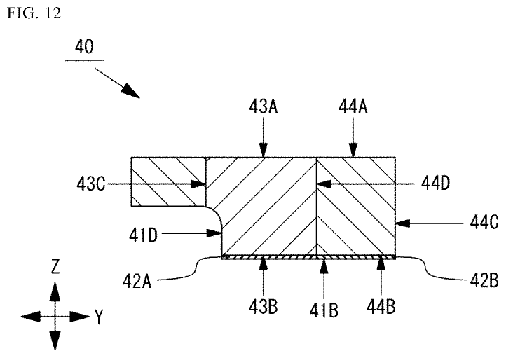

A light-emitting device 1 according to a first embodiment will now be described. FIGS. 1A to 12 are drawings for illustrating an exemplary form of the light-emitting device 1. FIG. 1A is a schematic perspective view of the light-emitting device 1. FIG. 1B is a schematic perspective view of the light-emitting device 1 illustrated in a transparent manner. FIG. 2A is a schematic top view of the light-emitting device 1 corresponding to FIG. 1B. FIG. 2B is a schematic bottom view of the light-emitting device 1. FIG. 3 is a schematic cross-sectional view of the light-emitting device 1 taken along a cross-sectional line III-III in FIG. 2A. FIG. 4 is a schematic top view of the light-emitting device 1, in a state in which a lid body 14 is removed. FIG. 5 is a schematic top view of the light-emitting device 1, in a state in which the lid body 14 and an optical member 40 are removed. FIG. 6 is a schematic perspective view of a submount 30. FIG. 7 is a schematic top view of the submount 30. In FIG. 7, a first conductive region 36A and a second conductive region 36B are indicated with hatching. FIG. 8 is a schematic bottom view of the submount 30. FIG. 9A is a schematic cross-sectional view of the submount 30 taken along the cross-sectional line IXA-IXA of FIG. 7. FIG. 9B is a schematic cross-sectional view of the submount 30 changed in scale from FIG. 9A for visibility to illustrate the structure of the submount 30. FIG. 10 is a schematic perspective view of the optical member 40. In FIG. 10, a first region 43M and a second region 43N are indicated with hatching. FIG. 11 is a schematic bottom view of the optical member 40. In FIG. 11, a reflective portion 42A and a conductive portion 42B are indicated with hatching. FIG. 12 is a schematic cross-sectional view of the optical member 40 taken along the cross-sectional line XII-XII in FIG. 10.

The light-emitting device 1 includes a plurality of components. The plurality of components include a package 10, a semiconductor laser element 20, the submount 30, the optical member 40, a protective element 50, and the plurality of wirings 60.

The light-emitting device 1 may include a component other than the components described above. For example, the light-emitting device 1 may further include a semiconductor laser element different from the semiconductor laser element 20. The light-emitting device 1 does not have to include some of the components described above.

Firstly, each of the components will be described.

### Package 10

The package 10 includes a base 11 and the lid body 14. The lid body 14 is joined to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the package 10 illustrated by the drawings, a short-side direction of the rectangular shape is the same direction as the X direction, and a long-side direction is the same direction as the Y direction. The outer edge shape of the package 10 in a top view does not have to be rectangular.

The internal space in which other components are disposed is formed in the package 10. A first upper surface 11A of the package 10 is a part of a region defining the internal space. In addition, inner lateral surfaces 11E and the lower surface 14B of the package 10 are a part of the region defining the internal space.

The base 11 has the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view does not have to be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. The step portion 11F includes an upper surface 11G and a lateral surface 11H that meets the upper surface 11G and extends downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is provided on an inner side of the inner frame of the second upper surface 11C in a top view. One or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The description “perpendicular” as used herein allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H face each other. The first step portion 11F1 and the second step portion 11F2 are provided on sides of the long sides of the inner frame of the second upper surface 11C.

The base 11 includes a base portion 11M and a frame portion 11N. The base portion 11M and the frame portion 11N may be members formed of mutually different materials. The base 11 can include a base member corresponding to the base portion 11M and a frame member corresponding to the frame portion 11N.

The base portion 11M has the first upper surface 11A. The frame portion 11N has the second upper surface 11C. The frame portion 11N has the one or more outer lateral surfaces 11D and the one or more inner lateral surfaces 11E. The frame portion 11N includes the one or more step portions 11F.

The lower surface of the base portion 11M partially or entirely constitutes the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The wiring portions 12A include one or more first wiring portions 12A1 disposed in the internal space of the package 10 and one or more second wiring portions 12A2 provided on the outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. One or each of the second wiring portions 12A2 is provided on the lower surface of the frame portion 11N. The second wiring portion 12A2 may be provided on an outer surface different from the lower surface 11B of the package 10.

When the base 11 is virtually divided into two regions by a virtual line passing through the lateral surface 11H of the first step portion 11F1 and parallel to the lateral surface 11H in a top view, the base 11 has the one or more second wiring portions 12A2 provided on the lower surface 11B of the base 11 in a region including the upper surface 11G of the first step portion 11F1.

When the base 11 is virtually divided into two regions by a virtual line passing through the lateral surface 11H of the second step portion 11F2 and parallel to the lateral surface 11H in a top view, the base 11 has the one or more second wiring portions 12A2 provided on the lower surface 11B of the base 11 in a region including the upper surface 11G of the second step portion 11F2.

In the base 11, one or each of the first wiring portions 12A1 is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. In other words, when a certain material is the main material, the proportion of the material may be 100%.

The base 11 may be formed using a base member and a frame member formed of main materials different from each other. The base member can be formed using a main material having good heat dissipation, for example, a metal or a composite containing a metal, graphite, or diamond. Examples of the metal as the main material of the base member include, for example, copper, aluminum, and iron. Examples of the composite containing the metal as the main material of the base member include, for example, copper-molybdenum and copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has an upper surface 14A and a lower surface 14B. The lid body 14 also has one or more lateral surfaces 14C. The lid body 14 is formed of a flat plate with a rectangular parallelepiped shape. The lid body 14 does not have to have a rectangular parallelepiped shape.

The lid body 14 is joined to the base 11. The lower surface 14B of the lid body 14 is joined to the second upper surface 11C of the base 11. The lid body 14 is joined to the bonding pattern 13A of the base 11. The lid body 14 is joined to the base 11 via an adhesive.

The lid body 14 has transmissivity to transmit light. The description “transmissivity” as used herein refers to that the transmittance for light incident on the lid body 14 is equal to or more than 80%. The lid body 14 may partially include a non-light transmitting region (a region with no transmissivity).

The lid body 14 can be formed using glass as a main material, for example. The lid body 14 can also be formed using sapphire as a main material, for example.

### Semiconductor Laser Element 20

The semiconductor laser element 20 has an upper surface 21A, a lower surface 21B, and a plurality of lateral surfaces 21C. A shape of the upper surface 21A is a rectangle having long sides and short sides. An outer shape of the semiconductor laser element 20 in a top view is a rectangle having long sides and short sides. The shape of the upper surface 21A and the outer shape of the semiconductor laser element 20 in the top view are not limited thereto.

The semiconductor laser element 20 has a light-emitting surface 22 from which light is emitted. For example, the lateral surface 21C may serve as the light-emitting surface 22. The lateral surface 21C serving as the light-emitting surface 22 meets a short side of the upper surface 21A. For example, the upper surface 21A can serve as the light-emitting surface 22.

As the semiconductor laser element 20, a single-emitter semiconductor laser element including one emitter can be employed. As the semiconductor laser element 20, a multi-emitter semiconductor laser element including a plurality of emitters can be employed.

The light emitted from the light-emitting surface 22 of the semiconductor laser element 20 is light of class 4 in accordance with the JIS standard “JIS C 6802:2018”. Because the JIS standard “JIS C 6802:2018” is created based on the IEC standard “IEC 60825-1:2014” and Interpretation sheet 1 and Interpretation sheet 2 issued in 2017 for the IEC standard, it can be said that a class in the JIS standard is a class based on the IEC standard.

The semiconductor laser element 20 emits light having light emission peak wavelengths in a range from 320 nm to 530 nm. Alternatively, the semiconductor laser element 20 emits light having light emission peak wavelengths in a range from 430 nm to 480 nm. An example of the semiconductor laser element 20 that emits light having such a light emission peak wavelength is a semiconductor laser element including a nitride semiconductor. A GaN-based semiconductor, such as GaN, InGaN, or AlGaN, can be employed as the nitride semiconductor. The light emitted from the semiconductor laser element 20 does not have to be limited to the wavelength ranges described above.

The semiconductor laser element 20 emits a directional laser beam. Divergent light that spreads is emitted from the light-emitting surface 22 (emission end surface) of the semiconductor laser element 20. The light emitted from the semiconductor laser element 20 forms a far-field pattern (hereinafter referred to as an “FFP”) with an elliptical shape in a plane parallel to the light-emitting surface 22. The FFP indicates a shape or a light intensity distribution of the emitted light at a position separated from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as a main portion of the light.

The shape of the FFP of the light emitted from the semiconductor laser element 20 has an elliptical shape in which a length in a layering direction is longer than that in a direction perpendicular to the layering direction in the plane parallel to the light-emitting surface 22. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at the light intensity of 1/e² of the peak light intensity.

The divergence angle in the fast axis direction of the light emitted from the semiconductor laser element 20 may be in a range from 7.5 degrees to less than 45 degrees. The divergence angle of the light in the slow axis direction can be more than 0° and 5° or less. Also, the divergence angle of the light in the fast axis direction is greater than the divergence angle of the light in the slow axis direction.

### Submount 30

The submount 30 includes a first upper surface 31A, a lower surface 31B, and one or more lateral surfaces 31C. The first upper surface 31A may be referred to as a mounting surface on which other components are mounted. The shape of the first upper surface 31A is rectangular. The rectangular shape of the first upper surface 31A can have short sides and long sides. The shape of the first upper surface 31A does not have to be rectangular.

The submount 30 includes a second upper surface 31D in addition to the first upper surface 31A. The second upper surface 31D may be referred to as a mounting surface on which other components are mounted. A component different from the component mounted on the first upper surface 31A is mounted on the second upper surface 31D. In this manner, it can be said that the submount 30 is a mounting member on which the other components are mounted.

The second upper surface, 31D, is located above (at a higher position than) the first upper surface, 31A. A height difference between the second upper surface 31D and the first upper surface 31A is in a range from 15 μm to 100 μm. The first upper surface 31A and the second upper surface 31D may be configured by flat surfaces having the same height, that is, one flat surface.

The outer shape of the submount 30 in a top view is rectangular. The rectangular shape of the submount 30 can have short sides and long sides. The outer shape of the submount 30 in a top view does not have to be rectangular. The submount 30 can have an outer shape having a length in one direction (hereinafter, the direction is referred to as a short-length direction of the submount 30) smaller than a length in a direction (hereinafter, the direction is referred to as a longitudinal direction of the submount 30) perpendicular to the one direction in a top view. In the submount 30 illustrated by the drawings, the short-length direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The submount 30 includes a first conductive layer 34A and a second conductive layer 34B. The first conductive layer 34A and the second conductive layer 34B are provided on the upper surface side of the submount 30. The first conductive layer 34A and the second conductive layer 34B are provided on the substrate 32A. In the submount 30, the first conductive layer 34A and the second conductive layer 34B are separated from each other and are not electrically connected to each other.

In a top view, the first upper surface 31A overlaps the first conductive layer 34A. In a top view, the first upper surface 31A overlaps the second conductive layer 34B. In a top view, the second upper surface 31D overlaps the upper metal member 32B. In a top view, the second upper surface 31D does not overlap the second conductive layer 34B.

In the submount 30, the upper metal member 32B is electrically connected to the first conductive layer 34A. The first conductive layer 34A is provided in connection with the upper metal member 32B. For example, the upper metal member 32B is provided on the substrate 32A, and then the first conductive layer 34A is provided. Alternatively, for example, the first conductive layer 34A may be provided on the substrate 32A, and the upper metal member 32B may be provided on the first conductive layer 34A. In the submount 30, the upper metal member 32B is separated from the second conductive layer 34B and is not electrically connected to the second conductive layer 34B.

In a top view, the first conductive layer 34A is disposed in a region extending in one direction from the upper metal member 32B, and these are connected to each other. This direction is referred to as a connection direction. The longitudinal direction of the submount 30 may correspond to the connection direction. In the submount 30 illustrated by the drawings, the positive direction of Y may be referred to as the connection direction.

In a top view, the second conductive layer 34B is separated from the first conductive layer 34A in a direction perpendicular to the connection direction. A direction perpendicular to the connection direction is referred to as a separation direction. In a top view, the second conductive layer 34B is separated from the upper metal member 32B in the separation direction. In a top view, the second conductive layer 34B is provided such that both one virtual straight line and the other virtual straight line pass through certain points as follows. The one virtual straight line passes through a certain point on the first conductive layer 34A and is parallel to the separation direction. The other virtual straight line (ii) passes through a certain point on the upper metal member 32B, and is parallel to the separation direction. In a top view, the length of the second conductive layer 34B in the connection direction is greater than the length of the upper metal member 32B in the connection direction.

The length of the upper metal member 32B in the separation direction is 50% or greater of the length of the submount 30 in the separation direction. This makes it easier to dispose other components on the upper metal member 32B. The length of the upper metal member 32B in the separation direction may be in a range from 50% to 90% of the length of the submount 30 in the separation direction.

The length of the upper metal member 32B in the separation direction is less than the length of the first conductive layer 34A in the separation direction. The length of the upper metal member 32B in the separation direction is 70% or more of the length of the first conductive layer 34A in the separation direction. The length of the upper metal member 32B in the separation direction is preferably in a range from 85% to 98% of the length of the first conductive layer 34A in the separation direction. From the viewpoint of the heat dissipation performance of the upper metal member 32B, it is preferable that the upper metal member 32B has a length close to the length of the first conductive layer 34A as possible in the separation direction while ensuring separation from the second conductive layer 34B in the separation direction.

In a top view, the length of the second conductive layer 34B in the separation direction is less than the length of the first conductive layer 34A in the separation direction. In a top view, the length of the second conductive layer 34B in the separation direction is less than the length of the upper metal member 32B in the separation direction. In this way, the length of the submount 30 in the separation direction can be reduced.

In a top view, the outer shape of the upper metal member 32B is a rectangular shape with long sides and short sides. In a top view, the outer shape of the second conductive layer 34B is a rectangular shape with long sides and short sides. The long-side direction of the outer shape of the upper metal member 32B and the long-side direction of the outer shape of the second conductive layer 34B are the same direction. The term “same” used here includes a tolerance of ±2 degrees. In the submount 30 illustrated by the drawings, the long-side direction of the upper metal member 32B is the same direction as the longitudinal direction of the submount 30.

In a top view, in the longitudinal direction of the submount 30, the length of the submount 30 is less than twice the length of the upper metal member 32B. The length of the former is 1.2 times or more of the length of the latter.

The submount 30 includes a first bonding layer 35A and a second bonding layer 35B. The first bonding layer 35A is provided in a region that is a part of the first conductive layer 34A in a top view. The second bonding layer 35B is provided in a region that is a part of the second conductive layer 34B in a top view.

When the submount 30 is virtually divided into two regions by a virtual straight line that passes through a point on a line connecting the first conductive layer 34A and the upper metal member 32B and is parallel to the separation direction in a top view, both the first bonding layer 35A and the second bonding layer 35B are provided in one region and are not provided in the other region. In other words, the first bonding layer 35A and the second bonding layer 35B are provided only in the same one region of the virtually divided two regions.

In a top view, the first bonding layer 35A and the second bonding layer 35B are included in a rectangular region that is defined on the submount 30 and does not include the upper metal member 32B. The outer shapes of the first bonding layer 35A and the second bonding layer 35B are both rectangular in a top view.

In the submount 30, the first bonding layer 35A is electrically connected to the first conductive layer 34A, and the second bonding layer 35B is electrically connected to the second conductive layer 34B. In the submount 30, the first bonding layer 35A is not electrically connected to the second bonding layer 35B and the second conductive layer 34B. In the submount 30, the second bonding layer 35B is not electrically connected to the first bonding layer 35A and the first conductive layer 34A.

When the ratios of the lengths of the first bonding layer 35A, the second conductive layer 34B, and the upper metal member 32B in the direction parallel to the long-side direction with respect to the lengths in the direction parallel to the short-side direction are compared with each other in regard to the long-side direction and the short-side direction of the outer shape of the second conductive layer 34B in a top view, the first bonding layer 35A has the smallest ratio and the second conductive layer 34B has the largest ratio.

The thickness (length in the vertical direction) of the first conductive layer 34A is less than the thickness of the upper metal member 32B. The thickness of the second conductive layer 34B is less than the thickness of the upper metal member 32B. The sum of the thickness of the first conductive layer 34A and the thickness of the first bonding layer 35A is less than the thickness of the upper metal member 32B. The sum of the thickness of the second conductive layer 34B and the thickness of the second bonding layer 35B is less than the thickness of the upper metal member 32B.

The thickness of the upper metal member 32B is greater than the thickness of the first conductive layer 34A by 10 μm or more. The thickness of the upper metal member 32B is greater than the thickness of the first conductive layer 34A in a range from 15 μm to 100 μm. The thickness of the first conductive layer 34A and the thickness of the second conductive layer 34B are the same. The term “same” used here includes a tolerance of ±3 μm.

The first conductive region 36A, the second conductive region 36B, and an insulating region 36C are provided on the upper surface side of the submount 30. The first conductive region 36A, the second conductive region 36B, and an insulating region 36C are provided on the mounting surface including the first upper surface 31A and the second upper surface 31D.

The second conductive region 36B is insulated from the first conductive region 36A via the insulating region 36C. That is, in the submount 30, the first conductive region 36A and the second conductive region 36B do not conduct electricity between each other. When the first conductive region 36A and the second conductive region 36B are provided on a member having insulating properties like the substrate 32A, the insulating region 36C does not include a region overlapping the first conductive region 36A in a top view, and does not include a region overlapping the second conductive region 36B in a top view.

The first conductive region 36A includes a first region including the first upper surface 31A and a second region including the second upper surface 31D. The second conductive region 36B includes the first upper surface 31A but not the second upper surface 31D. The insulating region 36C includes a region that separates the first conductive region 36A and the second conductive region 36B from each other in a top view.

The area of the first conductive region 36A is larger than that of the second conductive region 36B in a top view. The first conductive region 36A includes the first conductive layer 34A and the upper metal member 32B. The second conductive region 36B includes the second conductive layer 34B.

The insulating region 36C has a shape with a length in the connection direction that is longer than the length in the separation direction in a top view. The insulating region 36C has a rectangular shape in a top view. In the separation direction, the length of the second conductive region 36B is greater than the length of the insulating region 36C. In the separation direction, the ratio of the sum of the length of the second conductive region 36B and the length of the insulating region 36C with respect to the length of the submount 30 is less than 50%. Alternatively, this ratio may be 40% or less.

In a top view, the submount 30 can be virtually divided into two regions by a virtual straight line extending in the connection direction such that the first conductive region 36A is included in one region and the second conductive region 36B is included in the other region. That is, the first conductive region 36A and the second conductive region 36B are provided such that the first conductive region 36A and the second conductive region 36B can be divided by one virtual straight line extending in the connection direction.

The first conductive region 36A does not include a plurality of conductive regions separated from each other by an insulating region in the region in a top view. That is, the number of conductive regions included in the first conductive region 36A is one. The second conductive region 36B does not include a plurality of conductive regions separated from each other by an insulating region in the region in a top view. That is, the number of conductive regions included in the second conductive region 36B is one.

The substrate 32A has an insulating property. The substrate 32A is formed of, for example, silicon nitride, aluminum nitride, or silicon carbide. It is preferable to select a ceramic with relatively good heat dissipation (having high thermal conductivity) as the main material of the substrate 32A.

A metal such as copper or aluminum is used as the main material of the upper metal member 32B. The upper metal member 32B includes one or more metal layers. The upper metal member 32B can include a plurality of metal layers formed using different metals as main materials.

A metal such as copper or aluminum is used as the main material of the lower metal member 32C. The lower metal member 32C includes one or more metal layers. The lower metal member 32C can include a plurality of metal layers formed using different metals as main materials.

The wiring layer 33 can be formed using a metal material as a main material. For example, the wiring layer 33 can be formed using AuSn solder (a metal layer of AuSn).

The first conductive layer 34A and the second conductive layer 34B can be formed using a metal material as a main material. Examples of the metal material as the main material of the first conductive layer 34A and the second conductive layer 34B include single-component metals, such as Cu, Ag, Ni, Au, Ti, Pt, Pd, Cr, and W, and alloys containing any of these metals. The first conductive layer 34A and the second conductive layer 34B can be constituted by one or more metal layers, for example.

The first bonding layer 35A and the second bonding layer 35B can be formed by using a metal material as a main material. The first bonding layer 35A and the second bonding layer 35B can be formed using an AuSn solder, for example.

The insulating region 36C is, for example, a portion where the substrate 32A is exposed from the first conductive layer 34A, the second conductive layer 34B, and the upper metal member 32B in a top view. Instead of exposing the substrate 32A, an insulating layer may be further provided at the exposed portion.

For example, the length of the submount 30 in the short-side direction or the short-length direction is in a range from 600 μm to 1400 μm. The length of the submount 30 in the long-side direction or the longitudinal direction is in a range from 1500 μm to 5000 μm. A difference between the length in the longitudinal direction and the length in the short-length direction of the submount 30 is in a range from 100 μm to 4400 μm.

For example, the thickness of the submount 30 (the length in a direction perpendicular to the first upper surface 31A) is in a range from 130 μm to 600 μm. For example, the thickness of the substrate 32A is in a range from 100 μm to 400 μm. Also, for example, a thickness of the upper metal member 32B is in a range from 15 μm to 100 μm. Also, for example, a thickness of the lower metal member 32C is in a range from 15 μm to 100 μm. For example, the thickness of the wiring layer 33 is in a range from 0.3 μm to 5 μm.

### Optical Member

The optical member 40 includes an upper surface 41A, a lower surface 41B, and one or more lateral surfaces 41C. The shape of the upper surface 41A is rectangular. The shape of the lower surface 41B is rectangular.

The optical member 40 includes a light incident surface 41D and a light-exiting surface 41E. The one or more lateral surfaces 41C include the lateral surface 41C serving as the light incident surface 41D. The one or more lateral surfaces 41C or the upper surface 41A include a surface serving as the light-exiting surface 41E. In the optical member 40 illustrated by the drawings, the upper surface 41A includes the light-exiting surface 41E.

The light incident on the light incident surface 41D of the optical member 40 exits from the light-exiting surface 41E. At this time, the light exiting from the light-exiting surface 41E is light obtained by applying an optical effect to the light incident on the light incident surface 41D. The optical effect provided by the optical member 40 is an optical effect that enhances safety to the human body. For example, the optical member 40 applies an optical effect of diffusing the laser light incident on the light incident surface 41D and the light exits from the light-exiting surface 41E. Examples of other members that provide such optical effect include a diffusion plate, a phosphor plate, and the like. The optical member 40 illustrated by the drawings includes a wavelength conversion member 43 containing a phosphor.

The optical member 40 includes the wavelength conversion member 43 and a reflective member 44. The outer surface of the optical member 40 includes the outer surface of the wavelength conversion member 43 and the outer surface of the reflective member 44. In the optical member 40, a portion(s) of the wavelength conversion member 43 is exposed from the reflective member 44 and other portions are covered by the reflective member 44. The portion(s) of the wavelength conversion member 43 exposed from the reflective member 44 may correspond to the light incident surface 41D and the light-exiting surface 41E.

The optical member 40 includes a metal member 42. The metal member 42 includes the reflective portion 42A provided on the wavelength conversion member 43 and the conductive portion 42B provided on the reflective member 44.

The wavelength conversion member 43 includes an upper surface 43A, a lower surface 43B, and a plurality of lateral surfaces 43C. In the optical member 40, the upper surface 43A is exposed from the reflective member 44. The plurality of lateral surfaces 43C include the lateral surface 43C exposed from the reflective member 44 and the lateral surface 43C not exposed from the reflective member 44. The lateral surface 43C exposed from the reflective member 44 correspond to the light incident surface 41D of the optical member 40, and the upper surface 43A corresponds to the light-exiting surface 41E of the optical member 40.

In the wavelength conversion member 43, all the lateral surfaces 43C except the lateral surface 43C corresponding to the light incident surface 41D are covered with the reflective member 44. Light exiting from all the lateral surfaces 43C except the light incident surface 41D is reflected by the reflective member 44. Thus, light can be efficiently emitted from the light-exiting surface 41E of the optical member 40.

The reflective member 44 includes an upper surface 44A, a lower surface 44B, and one or more outer lateral surfaces 44C, and one or more inner lateral surfaces 44D. The one or more inner lateral surfaces 44D are in contact with the one or more lateral surfaces 43C of the wavelength conversion member 43.

The upper surface 41A of the optical member 40 includes the upper surface 43A of the wavelength conversion member 43 and the upper surface 44A of the reflective member 44 surrounding the upper surface 43A in a top view. That is, the upper surface 41A of the optical member 40 is constituted by the upper surface of two or more members. The upper surfaces of these members are flush with each other. The term “flush” used here includes a height tolerance within ±5 μm. The upper surfaces of these members do not have to be flush.

The lower surface 41B of the optical member 40 includes the lower surface 43B of the wavelength conversion member 43 and the lower surface 44B of the reflective member 44. That is, the lower surface 41B of the optical member 40 is constituted by the lower surface of two or more members. The lower surfaces of these members are flush with each other. The term “flush” used here includes a height tolerance within ±5 μm.

The plurality of lateral surfaces 41C of the optical member 40 include the lateral surface 43C corresponding to the light incident surface 41D of the wavelength conversion member 43 and the one or more outer lateral surfaces 44C of the reflective member 44. Also, the plurality of lateral surfaces 41C of the optical member 40 include the lateral surface 41C including the lateral surface 43C corresponding to the light incident surface 41D of the wavelength conversion member 43 and the outer lateral surface 44C of the reflective member 44. That is, the plurality of lateral surfaces 41C of the optical member 40 include the lateral surface 41C constituted by the lateral surface of two or more members.

Here, a direction from the lateral surface 41C where the light incident surface 41D of the optical member 40 is provided to the lateral surface 41C on the opposite side thereof is referred to as an incident direction. The upper surface 43A of the wavelength conversion member 43 includes the first region 43M in which, in a plan view perpendicular to the upper surface 43A, the length in a direction perpendicular to the incident direction increases toward the incident direction. The upper surface 43A of the wavelength conversion member 43 includes the second region 43N that extends in the incident direction from the first region 43M and in which, in a plan view perpendicular to the upper surface 43A, the length in a direction perpendicular to the incident direction decreases toward the incident direction. In the optical member 40 illustrated by the drawings, the incident direction is the same direction as the positive direction of Y, and the direction perpendicular to the incident direction is the same direction as the X direction.

The upper surface 43A of the wavelength conversion member 43 has a rectangular shape. One of the two diagonal lines of this rectangle is parallel to the incident direction. The other diagonal line is the boundary between the first region 43M and the second region 43N. The term “parallel” here includes a tolerance of ±2 degrees.

The light incident surface 41D of the wavelength conversion member 43 has a shape in which the maximum length in the vertical direction is greater than the maximum length in the direction perpendicular to the incident direction in a top view. In the direction perpendicular to the incident direction in a top view, the maximum length of the light incident surface 41D is greater than the minimum length of the light-exiting surface 41E of the wavelength conversion member 43 and less than the maximum length thereof.

The area of the lower surface 43B of the wavelength conversion member 43 is less than the area of the upper surface 43A of the wavelength conversion member 43. In a plan view perpendicular to the upper surface 43A of the wavelength conversion member 43, the first region 43M includes a region overlapping the lower surface 43B and a region overlapping the light incident surface 41D that does not overlap the lower surface 43B.

The shape of the upper surface 44A of the reflective member 44 is a rectangle having sides parallel to the incident direction. The shape of the upper surface 44A may be a shape other than a rectangle, such as a circle, and it is only required to surround the light-exiting surface 41E in a top view.

The metal member 42 is provided on the lower surface 41B of the optical member 40. The metal member 42 is provided on the opposite side to the light-exiting surface 41E. The metal member 42 provided on the lower surface 43B of the wavelength conversion member 43 corresponds to the reflective portion 42A that reflects light. The optical member 40 can be said to include the reflective portion 42A. The metal member 42 provided on the lower surface 44B of the reflective member 44 corresponds to the conductive portion 42B forming a portion of the current path. The optical member 40 can be said to include the conductive portion 42B.

The reflective portion 42A and the conductive portion 42B are connected to each other. The metal member 42 being a connected member of the reflective portion 42A and the conductive portion 42B makes forming the metal member 42 easy.

The reflective portion 42A may be formed not as a part of the metal member 42 but formed separately. In this case, the material for forming the reflective portion 42A is not limited to metals.

The metal member 42 is formed with a thickness of 5 μm or less. When the thickness of the metal member 42 is small, the position where the wavelength conversion member 43 is disposed with respect to the semiconductor laser element 20 is lowered, which leads to decreasing the size of the light-emitting device 1.

The reflective portion 42A is formed with a thickness of 1 μm or greater. Accordingly, the reflective portion 42A can exhibit sufficient reflectivity. The conductive portion 42B is formed with a thickness of 0.3 μm or greater. Thus, the stability of the current path is ensured. Accordingly, it can be said that the metal member 42 including the reflective portion 42A and the conductive portion 42B connected preferably has a thickness of 1 μm or greater.

The reflective portion 42A reflects 90% or more of the light incident on the reflective portion 42A. The reflective portion 42A is preferably provided on the entire lower surface 43B of the wavelength conversion member 43. The conductive portion 42B is provided on a portion or all of the lower surface 44B of the reflective member 44.

The wavelength conversion member 43 contains a phosphor. Examples of the phosphor include cerium-activated yttrium aluminum garnet (YAG), cerium-activated lutetium aluminum garnet (LAG), europium-activated silicate ((Sr, Ba)₂SiO₄), α-SiAlON phosphor, and β-SiAlON phosphor. Among them, the YAG phosphor has good heat resistance.

The wavelength conversion member 43 is preferably formed using an inorganic material that is not easily decomposed by light irradiation as a main material. An example of the main material of the wavelength conversion member 43 is a ceramic, for example. The main material is not limited to a ceramic. Furthermore, the wavelength conversion member 43 may be made of a single crystal of the phosphor. Examples of a ceramic include, for example, aluminum oxide, aluminum nitride, silicon oxide, yttrium oxide, zirconium oxide, and magnesium oxide. The wavelength conversion member 43 is, for example, a sintered compact formed by using a ceramic as the main material. The wavelength conversion member 43 can be formed by sintering, for example, a phosphor and a light-transmissive material such as aluminum oxide. The content of the phosphor can be in a range from 0.05 vol % to 50 vol % with respect to the total volume of the ceramic. Alternatively, for example, a ceramic made by sintering a powder of the phosphor, that is, a ceramic substantially consisting of only the phosphor may be used.

An example of the main material of the reflective member 44 is a ceramic, for example. Examples of the ceramic used as the main material includes, for example, aluminum oxide, aluminum nitride, silicon oxide, yttrium oxide, zirconium oxide, and magnesium oxide. The reflective member 44 is, for example, a sintered body formed of a ceramic as a main material. The reflective member 44 may not contain a ceramic as the main material.

The optical member 40 can be formed by integrally forming together the wavelength conversion member 43 and the reflective member 44. For example, the optical member 40 can be formed by integrally sintering the wavelength conversion member 43 and the reflective member 44.

The metal member 42 can be formed by using, for example, a metal material such as silver, aluminum, or the like.

### Protective Element 50

The protective element 50 has an upper surface 51A, a lower surface 51B, and one or more lateral surfaces 51C. The shape of the protective element 50 is a rectangular parallelepiped. The shape of the protective element 50 does not have to be a rectangular parallelepiped.

The protective element 50 prevents breakage of a specific element (the semiconductor laser element, for example) by an excessive current flowing through the element. The protective element 50 is, for example, a Zener diode. A Zener diode formed of Si can be used.

### Wiring 60

The wiring 60 is a linear conductive material having joining portions at both ends. The joining portions at both ends serve as portions for joining with other components. The wiring 60 is used for electrical connection between two components. The wiring 60 is, for example, a metal wire. The metal used can be, for example, gold, aluminum, silver, or copper.

Subsequently, the light-emitting device 1 will be described.

### Light-Emitting Device 1

In the light-emitting device 1, the semiconductor laser element 20 is disposed in the internal space of the package 10. The semiconductor laser element 20 is disposed on the first upper surface 11A. By disposing the semiconductor laser element 20 in a closed space, a decrease in the light output of the semiconductor laser element 20 by dust collection can be suppressed. By forming the internal space as a sealed space, the effects of dust collection can be further reduced.

The light-emitting surface 22 of the semiconductor laser element 20 faces the inner lateral surface 11E. The semiconductor laser element 20 emits light laterally from the light-emitting surface 22. A direction in which light is emitted from the light-emitting surface 22 is referred to as the first direction. Further, in a top view, a direction perpendicular to the first direction is referred to as the second direction. In the light-emitting device 1 illustrated by the drawings, the light-emitting surface 22 faces the positive direction of Y. The positive direction of Y may be referred to as the first direction, and the second direction may be referred to as the X direction.

Light emitted from the semiconductor laser element 20 along the optical axis travels in the first direction from the light-emitting surface 22. The light-emitting surface 22 of the semiconductor laser element 20 is parallel to the inner lateral surface 11E of the package 10 in a top view. The inner lateral surface 11E is an inner lateral surface to which the light-emitting surface 22 faces.

The semiconductor laser element 20 is mounted on the submount 30. The submount 30 is disposed on the first upper surface 11A. The semiconductor laser element 20 is disposed on the first upper surface 11A via the submount 30. The semiconductor laser element 20 is disposed in the first conductive region 36A. The semiconductor laser element 20 is disposed in the second region of the first conductive region 36A.

The semiconductor laser element 20 is electrically connected to the first conductive region 36A. One electrode of the semiconductor laser element 20 is electrically connected to the first conductive region 36A. More specifically, the electrode provided on the lower surface 21B side of the semiconductor laser element 20 is connected to the first conductive region 36A.

The semiconductor laser element 20 is disposed on the upper metal member 32B. The semiconductor laser element 20 is disposed on the second upper surface 31D. The semiconductor laser element 20 is disposed on the wiring layer 33. By providing the upper metal member 32B, the position of the light emission point of light on the light-emitting surface 22 can be made higher than the case of being disposed on the first upper surface 31A.

In this manner, the upper metal member 32B is electrically connected to the semiconductor laser element 20 and forms a step for adjusting the height of the semiconductor laser element 20. From such a point of view, it is sufficient that the light-emitting device 1 includes a conductive platform member forming the second upper surface 31D, and the upper metal member 32B can be regarded as an example of the conductive platform member.

When the mounting surface of the submount 30 is virtually divided into two regions by a virtual straight line that passes through the middle point of the second upper surface 31D in the second direction and is parallel to the first direction, the emission point of light on the light-emitting surface 22 is located in, of the two regions, the region that includes the second conductive region 36B. The semiconductor laser element 20 is mounted on the second upper surface 31D at a position closer to the second conductive region 36B. Accordingly, heat generated from the components disposed on the second upper surface 31D is easily spread to the second conductive region 36B side of the submount 30.

In a top view, the semiconductor laser element 20 is disposed at a position through which a virtual straight line that passes through a midpoint of the length of the submount 30 in the second direction and is parallel to the first direction passes. Thus, heat generated from the components disposed on the second upper surface 31D can be easily spread over the entire submount 30

The submount 30 is disposed in the package 10 such that the longitudinal direction of the submount 30 is parallel to the first direction. In a top view, the length of the submount 30 in the longitudinal direction is 60% or more of the length of the inner frame of the package in the first direction. Alternatively, the length of the submount 30 in the longitudinal direction may be 75% or more of the length of the inner frame of the package in the first direction. This can reduce extra space, resulting in reduction in the size of the light-emitting device 1.

In the light-emitting device 1, the optical member 40 is disposed in the internal space of the package 10. The optical member 40 is disposed on the first upper surface 11A. The optical member 40 is mounted on the submount 30. The optical member 40 is disposed on the first upper surface 11A via the submount 30.

The optical member 40 is disposed on the mounting surface of the submount 30 such that the conductive portion 42B and the mounting surface of the submount 30 are opposed to each other. The optical member 40 is disposed on the mounting surface of the submount 30 such that the conductive portion 42B overlaps the first conductive region 36A and the second conductive region 36B in a plan view seen along a direction perpendicular to the mounting surface of the submount 30. Thus, the semiconductor laser element 20 electrically connected to the first conductive region 36A is electrically connected to the second conductive region 36B via the conductive portion 42B. The semiconductor laser element 20 is not electrically connected to the second conductive region 36B unless passing through the conductive portion 42B.

In the light-emitting device 1 illustrated by the drawings, a plan view seen along a direction perpendicular to the mounting surface of the submount 30 is also a top view of the submount 30. A plan view seen along a direction perpendicular to the mounting surface of the submount 30 is also a top view of the optical member 40. A plan view seen along a direction perpendicular to the mounting surface of the submount 30 is also a top view of the semiconductor laser element 20. A plan view seen along a direction perpendicular to the mounting surface of the submount 30 is also a top view of the package 10.

With this electrical connection, when the optical member 40 is detached from the submount 30, the electrical connection between the conductive portion 42B and the first conductive region 36A and the second conductive region 36B is also interrupted, and the supply of electric power to the semiconductor laser element 20 is stopped. Thus, the light-emitting device 1 can achieve a configuration of stopping light emission from the semiconductor laser element 20 according to the state of the optical member 40.

Such an electrical connection makes it possible to detect an abnormality such as detachment or damage of the optical member 40. In addition, no component other than the optical member 40 is needed to electrically connect the semiconductor laser element 20 and the second conductive region 36B of the submount 30. Accordingly, it is possible to achieve a configuration of abnormality detection while reducing the number of components.

The optical member 40 is disposed in the first region of the first conductive region 36A. The optical member 40 is disposed on the first upper surface 31A. Thus, a height difference can be provided between the lower surface 21B of the semiconductor laser element 20 and the lower surface 41B of the optical member 40. That is, because the submount 30 includes the upper metal member 32B partially rather than entirely on the mounting surface, it is possible to adjust the relative height difference between the components disposed on the first upper surface 31A and the components disposed on the second upper surface 31D.

The conductive portion 42B overlaps the first conductive region 36A, the second conductive region 36B, and the insulating region 36C in a plan view seen along a direction perpendicular to the mounting surface of the submount 30. The conductive portion 42B connects the first bonding layer 35A and the second bonding layer 35B.

Light emitted from the light-emitting surface 22 of the semiconductor laser element 20 is incident on the light incident surface 41D of the optical member 40. The light incident surface 41D of the optical member 40 is disposed at a position spaced apart from the light-emitting surface 22 in the first direction. The light-emitting surface 22 faces the light incident surface 41D. The direction in which the light is incident on the optical member 40 is the same direction as the first direction.

The length of the semiconductor laser element 20 in the first direction is larger than the length of the wavelength conversion member 43 in the first direction. The length of the semiconductor laser element 20 in the first direction is larger than the length of the optical member 40 in the first direction. In the longitudinal direction of the submount 30, the length of the submount 30 is preferably in a range from 1.6 times to 3.2 times the length of the upper metal member 32B. When the sizes of the components are adjusted in order to emit a sufficient amount of light from the semiconductor laser element 20 and to perform sufficient wavelength conversion via the wavelength conversion member 43, this multiplying factor range is preferable.

The length of the optical member 40 in the second direction is greater than the length of the second upper surface 31D in the second direction. The length of the wavelength conversion member 43 in a direction that is parallel to the second direction and passes through a middle point of the length in the first direction is less than the length of the second upper surface 31D in the second direction. When the optical member 40 including the reflective member 44 and having high light extraction efficiency is mounted on the mounting surface of the submount 30, a structure satisfying these conditions is suitable for reducing the size of the light-emitting device 1.

The length of the optical member 40 in the second direction is greater than a value equal to the length of the submount 30 in the second direction minus 600 μm. The length of the optical member 40 in the second direction is less than a value equal to the length of the submount 30 in the second direction plus 600 μm. The length of the optical member 40 in the second direction is preferably less than the length of the submount 30 in the second direction. When the difference between the lengths of the optical member 40 and the submount 30 in the second direction is small, extra space is reduced, which contributes to reducing the size of the light-emitting device 1.

The reflective portion 42A is disposed on the mounting surface of the submount 30 so as to overlap the first conductive region 36A and not to overlap the second conductive region 36B in a plan view seen along a direction perpendicular to the mounting surface of the submount 30. Accordingly, it is possible to reduce the area in which the reflective portion 42A and the insulating region 36C overlap in this plan view and to improve the effect of heat dissipation from the wavelength conversion member 43 to the submount 30.

The reflective portion 42A may overlap the insulating region 36C in a plan view seen along a direction perpendicular to the mounting surface of the submount 30. Thus, compared to a case in which the reflective portion 42A is disposed so as to be enclosed within the first conductive region 36A in this plan view, the submount 30 can be made smaller in length in the second direction, which contributes to reducing the size of the light-emitting device 1.

A point at which the wavelength conversion member 43 and the insulating region 36C overlap each other in a plan view seen along a direction perpendicular to the mounting surface of the submount 30 is present on a virtual straight line that passes through a midpoint of the length of the wavelength conversion member 43 in the first direction and is parallel to the second direction. In a plan view seen along a direction perpendicular to the mounting surface of the submount 30, a ratio of the area where the wavelength conversion member 43 and the insulating region 36C overlap with each other with respect to the area of the light-exiting surface 41E is 5% or less. The shape of the light-exiting surface 41E including the first region 43M and the second region 43N is suitable for reducing the area in which the wavelength conversion member 43 and the insulating region 36C overlap each other.

Light emitted from the semiconductor laser element 20 and incident on the light incident surface 41D of the optical member 40 exits from the light-exiting surface 41E. When the optical member 40 includes the wavelength conversion member 43, the wavelength-converted light emitted from the semiconductor laser element 20 exits from the light-exiting surface 41E. At this time, not only the wavelength-converted light, but also a part of the light emitted from the semiconductor laser element 20 (i.e., non-wavelength converted light) may be emitted without being wavelength-converted.

For example, white color light including a mixture of light with a light emission peak wavelength in a range from 430 nm to 480 nm and light wavelength-converted by the YAG phosphor is emitted from the light-exiting surface 41E of the wavelength conversion member 43.

The light emitted from the light-exiting surface 41E of the optical member 40 is light of a class 3R in accordance with the JIS standard “JIS C 6802:2018” or light with a risk lower than class 3R. The light-emitting device 1 emits light with enhanced safety by emitting the light through the optical member 40 instead of emitting the light directly from the semiconductor laser element 20.

At least a part of the light incident on the optical member 40 is reflected by the reflective member 44 before exiting from the light-exiting surface 41E. At least a part of the light incident on the optical member 40 is reflected by the reflective portion 42A before exiting from the light-exiting surface 41E. Thus, light can efficiently exit from the light-exiting surface 41E. When the optical member 40 includes the wavelength conversion member 43, the wavelength conversion efficiency can also be improved.

The optical member 40 generates heat upon light being incident and emitted. The larger the area of the reflective portion 42A joined to the first conductive layer 34A is, the more the heat dissipation effect is improved.

In the light-emitting device 1, the protective element 50 is disposed in the internal space of the package 10. The protective element 50 is disposed on the first upper surface 11A. The protective element 50 is mounted on the submount 30. The protective element 50 is disposed on the first upper surface 11A via the submount 30.

The protective element 50 is disposed on the second upper surface 31D of the submount 30. The semiconductor laser element 20 is located between the protective element 50 and the second conductive region 36B in the second direction.

In the light-emitting device 1, the plurality of wirings 60 are disposed in the internal space of the package 10. By providing the plurality of wirings 60, the semiconductor laser element 20 is electrically connected to the base 11. Furthermore, the protective element 50 is also electrically connected to the base 11.

The plurality of wirings 60 include the wiring(s) 60 provided to electrically connect the semiconductor laser element 20 to the base 11. The plurality of wirings 60 include the wiring(s) 60 provided to electrically connect the protective element 50 to the base 11.

The plurality of wirings 60 include first wiring(s) 60A and second wiring(s) 60B. The first wiring(s) 60A and the second wiring(s) 60B are joined to different wiring portions 12A. The first wiring(s) 60A and the second wiring(s) 60B are joined to the first wiring portion 12A1 of the base 11.

Of the first wiring(s) 60A and the second wiring(s) 60B, one wiring 60 is joined to the semiconductor laser element 20, and the other wiring 60 is joined to the second conductive region 36B. In the light-emitting device 1 illustrated by the drawings, the first wirings 60A are joined to the semiconductor laser element 20, and the second wirings 60B are joined to the second conductive region 36B. The second wirings 60B are joined to a region of the second conductive layer 34B where the second bonding layer 35B is not provided.

Because the length of the optical member 40 in the second direction is larger than that of the semiconductor laser element 20 in the second direction, by providing the wirings 60 in the space resulting from the difference in these length, it is possible to suppress an increase in the size of the submount 30 and to contribute to a reduction in the size of the light-emitting device 1.

In a top view, the distance from the optical member 40 to the lateral surface 31C of the submount 30 is less than the distance from the position on the submount 30 to which the second wiring 60B is joined to the lateral surface 31C. The lateral surface 31C is a lateral surface extending in the first direction. It is possible to obtain the light-emitting device 1 including the submount 30 satisfying such conditions.

The length of the second conductive layer 34B in the second direction is preferably in a range from 15% to 30% of the length of the first conductive layer 34A in the second direction. Accordingly, it is possible to reduce the region where the wavelength conversion member 43 and the insulating region 36C overlap as much as possible in a top view while maintaining the length for securing the joining region of the wirings 60.

The first wiring(s) 60A is provided on one electrode side of the two electrodes of the semiconductor laser element 20. The second wiring(s) 60B is provided on the other electrode side of the two electrodes. “Provided on the electrode side” can be defined as that this electrode is closer than the other electrode, which is the comparison target, on the current path.

The conductive portion 42B of the optical member 40 is not provided on the current path between the first wiring(s) 60A and one of the electrodes of the semiconductor laser element 20. The conductive portion 42B of the optical member 40 is provided on the current path between the second wiring(s) 60B and the other electrode of the semiconductor laser element 20.

In a top view, with the semiconductor laser element 20 as a reference, the first wiring portion 12A1 provided on one inner lateral surfaces 11E side of the two opposing inner lateral surfaces 11E of the base 11 and the first wiring(s) 60A are joined to each other, and the first wiring portion 12A1 provided on the other inner lateral surface 11E side and the second wiring(s) 60B are joined to each other. Each of these two inner lateral surfaces 11E does not face the light-emitting surface 22 of the semiconductor laser element 20, but is the inner lateral surface 11E facing the lateral surface 21C meeting the light-emitting surface 22.

When the base 11 is virtually divided into two portions by a virtual straight line that is parallel to the first direction and passes through the insulating region 36C in a top view, the first wiring(s) 60A is joined to one portion of the base 11 and the second wiring(s) 60B is joined to the other portion of the base 11.

The semiconductor laser element 20 is electrically connected to the second wiring portions 12A2 of the base 11. The semiconductor laser element 20 is electrically connected to the second wiring portion 12A2 via the first wiring portion 12A1. In the base 11, a second wiring portion 12A2 electrically connected to the first wiring portion 12A1 to which the first wiring(s) 60A is joined and the second wiring portion 12A2 electrically connected to the first wiring portion 12A1 to which the second wiring 60B is joined are different wiring portions 12A.

Among the plurality of wirings 60, the first wiring 60A and the second wiring 60B are included in all of the wirings 60 present on the current path from the second wiring portion 12A2 provided on the side closer to one electrode of the semiconductor laser element 20 to the second wiring portion 12A2 provided on the side closer to the other electrode. When the base 11 is virtually divided into two portions by a virtual straight line that passes through the light-emitting surface 22 of the semiconductor laser element 20 and is parallel to the second direction in a top view, all the wirings 60 are provided in one portion of the base 11 and are not provided in the other portion of the base 11.

The first wiring 60A is joined to the first wiring portion 12A1 provided on the first step portion 11F1. The second wiring 60B is joined to the first wiring portion 12A1 provided on the second step portion 11F2. In the light-emitting device 1, the number of wiring portions 12A to which the wirings 60 are joined may be two. This can reduce the number of parts.

In the light-emitting device 1, the light exiting from the light-exiting surface 41E exits from the upper surface 14A. The light exiting from the upper surface 14A may correspond to light emitted from the light-emitting device 1. The light emitted from the semiconductor laser element 20 and the light wavelength-converted by the wavelength conversion member 43 are combined and emitted from the light-emitting device 1. In this manner, white light can be emitted from the light-emitting device 1.

### Second Embodiment

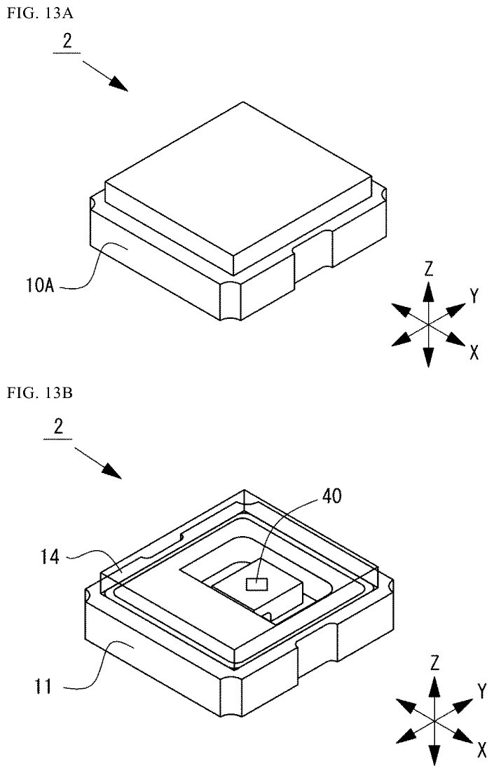

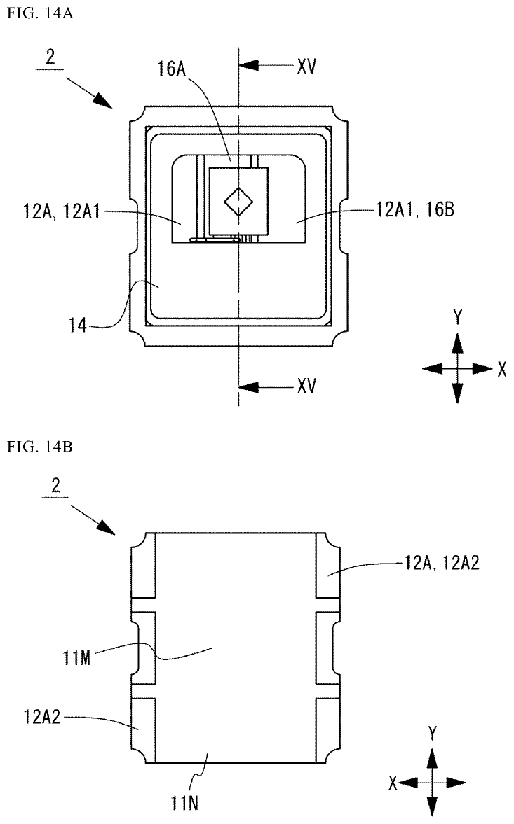

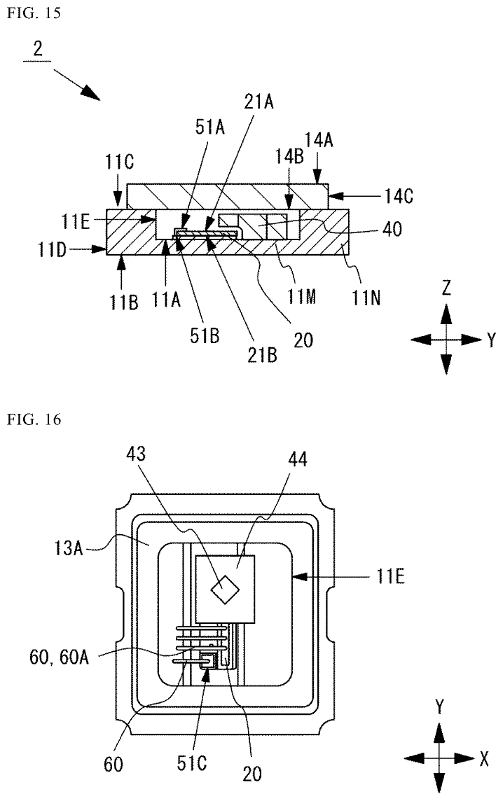

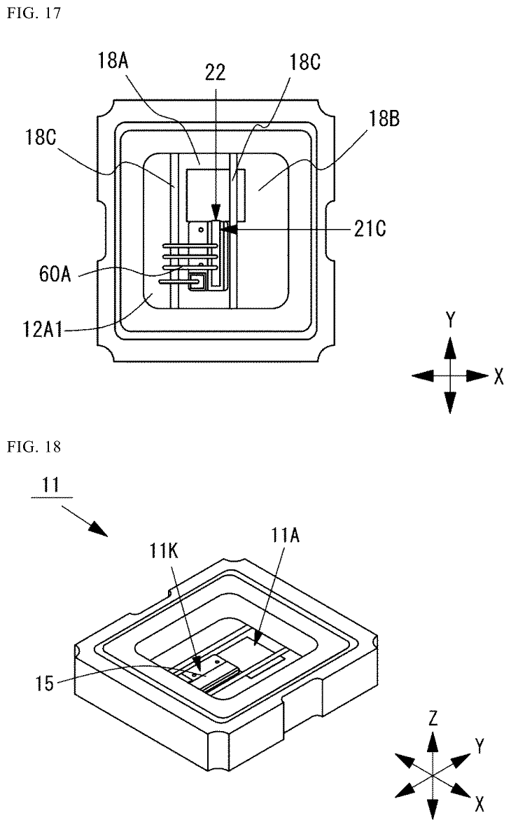

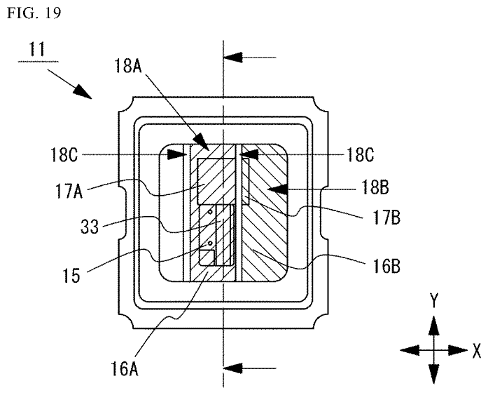

A light-emitting device 2 according to the second embodiment will now be described. FIGS. 10 to 19 are drawings for illustrating an exemplary form of the light-emitting device 2. FIG. 13A is a schematic perspective view of the light-emitting device 2. FIG. 13B is a schematic perspective view of the light-emitting device 2 illustrated in a transparent manner. FIG. 14A is a schematic top view of the light-emitting device 2 corresponding to FIG. 13B. FIG. 14B is a schematic bottom view of the light-emitting device 2. FIG. 15 is a schematic cross-sectional view of the light-emitting device 2 taken along a cross-sectional line XV-XV in FIG. 14A. FIG. 16 is a schematic top view of the light-emitting device 2, in a state in which the lid body 14 is removed. FIG. 17 is a schematic top view of the light-emitting device 2, in a state in which the lid body 14 and the optical member 40 are removed. FIG. 18 is a schematic perspective view of the base 11. FIG. 19 is a schematic top view of the base 11. In FIG. 19, a first conductive region 18A and a second conductive region 18B are indicated with hatching. FIG. 10 is a schematic perspective view of the optical member 40. In FIG. 10, a first region 43M and a second region 43N are indicated with hatching. FIG. 11 is a schematic bottom view of the optical member 40. In FIG. 11, a reflective portion 42A and a conductive portion 42B are indicated with hatching. FIG. 12 is a schematic cross-sectional view of the optical member 40 taken along the cross-sectional line XII-XII in FIG. 10.

In the description related to the light-emitting device 1 and each component of the first embodiment described above, all content excluding contents that is deemed to be contradictory from the drawings of FIGS. 10 to 19 related to the light-emitting device 2 are also applied as the description of the light-emitting device 2. All non-contradictory contents will not be repeated here in order to avoid duplication.

The description of the light-emitting device 1 according to the first embodiment described above applies to the light-emitting device 2 in terms of all of the content except for contradictory content from FIGS. 10 to 19 according to the light-emitting device 2, with the first upper surface 31A being substituted with the first upper surface 11A, the second upper surface 31D being substituted with a third upper surface 11K, the upper metal member 32B being substituted with a conductive member 15, the first conductive layer 34A being substituted with a first conductive layer 16A, the second conductive layer 34B being substituted with a second conductive layer 16B, the first bonding layer 35A being substituted with a first bonding layer 17A, the second bonding layer 35B being substituted with a second bonding layer 17B, the first conductive region 36A being substituted with a first conductive region 18A, the second conductive region 36B being substituted with a second conductive region 18B, the insulating region 36C being substituted with an insulating region 18C, and the mounting surface of the submount 30 being substituted with a mounting surface of the base 11. All non-contradictory contents will not be repeated here in order to avoid duplication.

The light-emitting device 2 includes a plurality of components. The plurality of components include a package 10A, the semiconductor laser element 20, the optical member 40, the protective element 50, and the plurality of wirings 60.

In the description related to the package 10 of the first embodiment described above, all contents excluding contents that are deemed to be contradictory to the package 10A from the drawings of FIGS. 10 to 19 related to the light-emitting device 2 are also applied as the description of the package 10A. All non-contradictory contents will not be repeated here in order to avoid duplication.

### Package 10A

The base 11 of the package 10A includes the third upper surface 11K. The third upper surface 11K is located above (at a higher position than) the first upper surface 11A and below the second upper surface 11C. The third upper surface 11K is a part of a region defining the internal space of the package 10A.

The third upper surface 11K is provided on an inner side of the inner frame of the second upper surface 11C in a top view. The base 11, in the recessed portion, includes a protruding portion protruding upward from the first upper surface 11A. The third upper surface 11K is a part of the protruding portion.

One or each of the first wiring portions 12A1 is provided on the first upper surface 11A. The base 11 includes the first wiring portion 12A1 provided at a position closer to one of the inner lateral surfaces 11E of the opposing inner lateral surfaces 11E, and the first wiring portion 12A1 provided at a position closer to the other inner lateral surface 11E.

The base 11 includes the first conductive layer 16A and the second conductive layer 16B. The first conductive layer 16A and the second conductive layer 16B are provided on the first upper surface 11A. The first conductive layer 16A and the second conductive layer 16B are separated from each other and are not electrically connected to each other.

In a top view, the third upper surface 11K overlaps the first conductive layer 16A. In a top view, the third upper surface 11K does not overlap the second conductive layer 16B. In a top view, the third upper surface 11K does not overlap the one or more first wiring portions 12A1.

The package 10A includes the conductive member 15. The conductive member 15 is provided on the first upper surface 11A. The conductive member 15 includes the third upper surface 11K. In the base 11, the conductive member 15 is electrically connected to the first conductive layer 16A. The first conductive layer 16A and the conductive member 15 are connected to each other.

In a top view, the first conductive layer 16A is disposed in a region extending in one direction from the conductive member 15, and these are connected to each other. This direction is referred to as a connection direction. The long-side direction of the inner frame of the second upper surface 11C may correspond to the connection direction. In the package 10A illustrated by the drawings, the positive direction of Y may be referred to as the connection direction.

In a top view, the second conductive layer 16B is separated from the first conductive layer 16A in a direction perpendicular to the connection direction. A direction perpendicular to the connection direction is referred to as a separation direction. In a top view, the second conductive layer 16B is separated from the conductive member 15 in the separation direction.

In the top view, the external shape of the conductive member 15 is a rectangular shape with long sides and short sides. The long-side direction of the outer shape of the conductive member 15 and the long-side direction of the inner frame of the second upper surface 11C are the same direction. The term “same” used here includes a tolerance of ±2 degrees.

In a top view, in the long-side direction of the inner frame of the second upper surface 11C, the length of the inner frame of the second upper surface 11C is less than three times the length of the conductive member 15. The length of the former is 1.7 times or more of the length of the latter.

The package 10A includes the first bonding layer 17A and the second bonding layer 17B. The first bonding layer 17A is provided in a region that is a part of the first conductive layer 16A in a top view. The second bonding layer 17B is provided in a region that is a part of the second conductive layer 16B in a top view.

When the first upper surface 11A is virtually divided into two regions by a virtual straight line that passes through a point on a line connecting the first conductive layer 16A and the conductive member 15 and is parallel to the separation direction in a top view, both the first bonding layer 17A and the second bonding layer 17B are provided in one region and are not provided in the other region. In other words, the first bonding layer 17A and the second bonding layer 17B are provided only in the same one region of these two regions.

In the base 11, the first bonding layer 17A is electrically connected to the first conductive layer 16A, and the second bonding layer 17B is electrically connected to the second conductive layer 16B. In the base 11, the first bonding layer 17A is not electrically connected to the second bonding layer 17B and the second conductive layer 16B. In the base 11, the second bonding layer 17B is not electrically connected to the first bonding layer 17A and the first conductive layer 16A. The second conductive layer 16B may correspond to the first wiring portion 12A1.

The thickness (length in the vertical direction) of the first conductive layer 16A is less than the thickness of the conductive member 15. The thickness of the second conductive layer 16B is less than the thickness of the conductive member 15. The sum of the thickness of the first conductive layer 16A and the thickness of the first bonding layer 17A is less than the thickness of the conductive member 15. The sum of the thickness of the second conductive layer 16B and the thickness of the second bonding layer 17B is less than the thickness of the conductive member 15.

The thickness of the conductive member 15 is greater than the thickness of the first conductive layer 16A by 10 μm or more. The thickness of the conductive member 15 is greater than the thickness of the first conductive layer 16A in a range from 15 μm to 100 μm. The thickness of the first conductive layer 16A and the thickness of the second conductive layer 16B are the same. The term “same” used here includes a tolerance of ±3 μm.

The first conductive region 18A, the second conductive region 18B, and the one or more insulating regions 18C are provided on the upper surface side of the base 11. The first conductive region 18A, the second conductive region 18B, and the one or more insulating regions 18C are provided on the mounting surface of the base 11 including the first upper surface 11A and the third upper surface 11K.

The second conductive region 18B is insulated from the first conductive region 18A via the insulating regions 18C. That is, in the base 11, the first conductive region 18A and the second conductive region 18B do not conduct electricity between each other. When the first conductive region 18A and the second conductive region 18B are provided on a member having insulating properties, the insulating region 18C does not include a region overlapping the first conductive region 18A in a top view, and does not include a region overlapping the second conductive region 18B in a top view.

The first conductive region 18A is insulated from the one or more first wiring portions 12A1 via the insulating regions 18C. That is, in the base 11, the first conductive region 18A and the one or more first wiring portions 12A1 do not conduct electricity between each other. When the first conductive region 18A and the first wiring portion 12A1 are provided on a member having insulating properties, the insulating region 18C does not include a region overlapping the first conductive region 18A in a top view, and does not include a region overlapping the first wiring portion 12A1 in a top view.

The first conductive region 18A includes a first region including the first upper surface 11A and a second region including the third upper surface 11K. The second conductive region 18B includes the first upper surface 11A but not the third upper surface 11K. The insulating region 18C includes a region that separates the first conductive region 18A and the second conductive region 18B from each other in a top view.

In a top view, the base 11 can be virtually divided into two regions by a virtual straight line extending in the connection direction such that the first conductive region 18A is included in one region and the second conductive region 18B is included in the other region. That is, the first conductive region 18A and the second conductive region 18B are provided such that the first conductive region 18A and the second conductive region 18B can be virtually divided by one virtual straight line extending in the connection direction.

The first conductive region 18A does not include a plurality of conductive regions separated from each other by an insulating region in the region thereof in a top view. That is, the number of conductive regions included in the first conductive region 18A is one. The second conductive region 18B does not include a plurality of conductive regions separated from each other by an insulating region in the region thereof in a top view. That is, the number of conductive regions included in the second conductive region 18B is one.

In the package 10A, the structure formed on the substrate 32A of the submount 30 of the light-emitting device 1 is monolithically formed as a part of the package 10. The structure including the mounting surface on which the first conductive region 18A, the second conductive region 18B, and the insulating region 18C are provided is a part of the package 10A.

### Light-Emitting Device 2

In the light-emitting device 2, the semiconductor laser element 20 is disposed on the third upper surface 11K. The semiconductor laser element 20 is mounted on the conductive member 15. In the light-emitting device 2, the optical member 40 is mounted on the base 11. The optical member 40 is mounted on the first upper surface 11A. In the light-emitting device 2, the protective element 50 is mounted on the base 11. The protective element 50 is mounted on the third upper surface 11K.

In the light-emitting device 2, when the optical member 40 is detached from the base 11, the electrical connection between the conductive portion 42B and the first conductive region 36A and the second conductive region 36B is also interrupted, and the supply of electric power to the semiconductor laser element 20 is stopped. Thus, the light-emitting device 2 can achieve a configuration of stopping light emission from the semiconductor laser element 20 according to the state of the optical member 40.

Although each of the embodiments according to the present disclosure has been described above, the light-emitting device according to the present disclosure is not strictly limited to the light-emitting device in each of the embodiments. In other words, the present disclosure can be achieved without being limited to the outer shape or structure of the light-emitting device disclosed by each of the embodiments. The present disclosure can be applied without requiring all the components being provided. For example, in a case in which some of the components of the light-emitting device disclosed by the embodiments are not stated in the claims, a degree of freedom in design by those skilled in the art such as substitutions, omissions, shape deformations, and material changes is allowed for those components, and then it is specified that the disclosure stated in the claims is applied to those components.

The light-emitting devices described in the embodiments can be used in lighting. That is, lighting can be said to be one application to which the present disclosure is applied. The present disclosure is not limited thereto, and can be used in various applications, such as projectors, exposure, on-vehicle headlights, head-mounted displays, backlights of other displays, and the like.

What is claimed is:

1. A light-emitting device comprising:
a semiconductor laser element having a light-emitting surface from which light is emitted;
an optical member having a light incident surface on which light emitted from the light-emitting surface of the semiconductor laser element is incident, the optical member including a conductive portion; and
a mounting member having a mounting surface on which a first conductive region, an insulating region, and a second conductive region are provided, the second conductive region being insulated from the first conductive region via the insulating region, wherein
the semiconductor laser element is disposed in the first conductive region of the mounting surface,
the optical member is disposed on the mounting surface such that the conductive portion and the mounting surface face each other and the conductive portion overlaps at least a portion of the first conductive region and at least a portion of the second conductive region in a plan view seen along a direction perpendicular to the mounting surface, and
the semiconductor laser element is electrically connected to the second conductive region via the conductive portion.

2. The light-emitting device according to claim 1, wherein
the first conductive region of the mounting surface of the mounting member includes
a first region having a first upper surface, and
a second region having a second upper surface located at a position higher than the first upper surface,
the semiconductor laser element is disposed in the second region of the first conductive region, and
a part of the optical member is disposed in the first region of the first conductive region.

3. The light-emitting device according to claim 2, wherein
the mounting member includes a first conductive layer, a second conductive layer, and a platform member having conductivity and forming the second upper surface,
the first upper surface overlaps the first conductive layer in the plan view,
the second upper surface overlaps the platform member in the plan view, and
a thickness of the first conductive layer is less than a thickness of the platform member.

4. The light-emitting device according to claim 1, wherein
the semiconductor laser element is configured to emit light in a first direction from the light-emitting surface,
the light incident surface of the optical member is disposed at a position spaced apart from the semiconductor laser element in the first direction, and
the light-emitting surface of the semiconductor laser element faces the light incident surface of the optical member.

5. The light-emitting device according to claim 1, wherein
the optical member has a light-exiting surface, and
the conductive portion is provided on a side opposite the light-exiting surface of the optical member.

6. The light-emitting device according to claim 1, wherein
the first conductive region has an area larger than an area of the second conductive region in the plan view.

7. The light-emitting device according to claim 1, further comprising:
a base including a plurality of wiring portions; and
a plurality of wirings including a first wiring and a second wiring joined to mutually different wiring portions of the plurality of wiring portions, wherein
the first wiring is joined to the semiconductor laser element, and
the second wiring is joined to the second conductive region.

8. The light-emitting device according to claim 1, further comprising
a package that defines an internal space where the semiconductor laser element and the optical member are disposed, wherein
the mounting member is a part of the package.

9. The light-emitting device according to claim 1, further comprising:
a package that defines an internal space where the semiconductor laser element and the optical member are disposed, wherein
the mounting member is disposed on a flat surface defining an internal space of the package.

10. The light-emitting device according to claim 1, wherein
the optical member has a light-exiting surface,
the light emitted from the light-emitting surface of the semiconductor laser element is class 4 light in accordance with JIS standard JIS C 6802:2018, and
light emitted from the light-exiting surface of the optical member is class 3R light or light with a risk lower than class 3R in accordance with JIS standard JIS C 6802:2018.
